(19) United States
(12) Patent Application Publication
(10) Pub. No.: US 2018/0097110 A1
(43) Pub. Date: Apr. 5, 2018

(54) METHOD FOR MANUFACTURING A SEMICONDUCTOR STRUCTURE

(71) Applicant: UNITED MICROELECTRONICS CORP., Hsinchu (TW)

(72) Inventors: Tsung-Mu Yang, Tainan City (TW); Kuang-Hsiu Chen, Tainan City (TW); Chun-Liang Kuo, Kaohsiung City (TW); Tsang-Hsuan Wang, Kaohsiung City (TW); Yu-Ming Hsu, Lukang Township (TW); Fu-Cheng Yen, Taipei City (TW); Chung-Min Tsai, Tainan City (TW)

(21) Appl. No.: 15/281,993

(22) Filed: Sep. 30, 2016

(51) Int. Cl. H01L 29/78; H01L 29/08; H01L 29/24; H01L 29/16; H01L 29/161; H01L 29/165; H01L 29/267; H01L 29/66; H01L 21/02

(52) U.S. Cl. CPC H01L 29/7848; H01L 29/0847; H01L 29/24; H01L 29/1608; H01L 29/161; H01L 21/02057; H01L 29/267; H01L 29/7851; H01L 29/66795; H01L 29/66636; H01L 29/165

(57) ABSTRACT

A method for manufacturing a semiconductor structure comprises the following steps. First, a recess is formed in a substrate. At least one wet cleaning process is performed to the recess and the substrate. Then, a baking process is performed to the recess and the substrate in an atmosphere containing H₂ gas. After the baking process, a dry cleaning process is performed the recess and the substrate.

### TECHNICAL FIELD

The disclosure relates to a method for manufacturing a semiconductor structure, particularly to a method comprising cleaning processes.

### BACKGROUND

Epitaxial structures are typically used in semiconductor devices. For example, they can be formed to replace conventional source/drain regions, so as to apply a strain to the channel for improving the performance of the device. For the manufacturing of epitaxial structures, it is important to provide the deposition process with a starting surface having good surface characteristics. As such, before the epitaxial deposition process, the starting surface should be cleaned to remove undesired residuals, such as polymers, oxides, and the like.

### SUMMARY

This disclosure is directed to a method for manufacturing a semiconductor structure. The method comprises several cleaning processes for providing a starting surface having good surface characteristics that may be beneficial for the formation of an epitaxial structure.

According to some embodiments, the method comprises the following steps. First, a recess is formed in a substrate. At least one wet cleaning process is performed to the recess and the substrate. Then, a baking process is performed to the recess and the substrate in an atmosphere containing H₂ gas. After the baking process, a dry cleaning process is performed to the recess and the substrate.

### BRIEF DESCRIPTION OF THE DRAWINGS

FIG. 1 is a flow diagram illustrating a method for manufacturing a semiconductor structure according to embodiments.

FIGS. 2A-2H illustrates stages of a semiconductor structure manufactured by a method according to embodiments.

FIGS. 3A-3B and 4A-4B illustrates the semiconductor structures of comparative examples.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

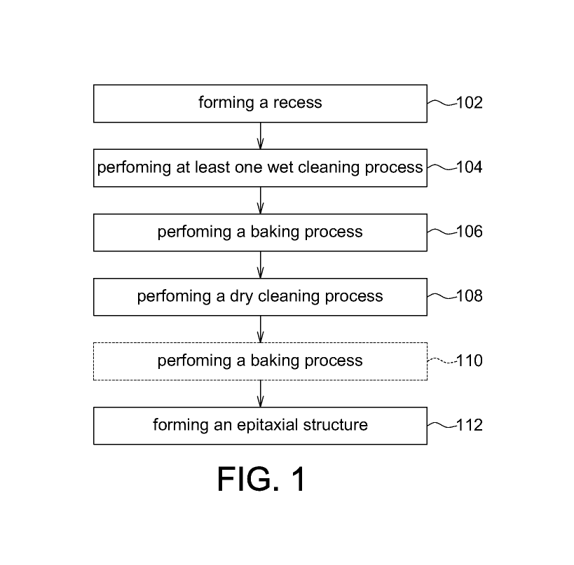

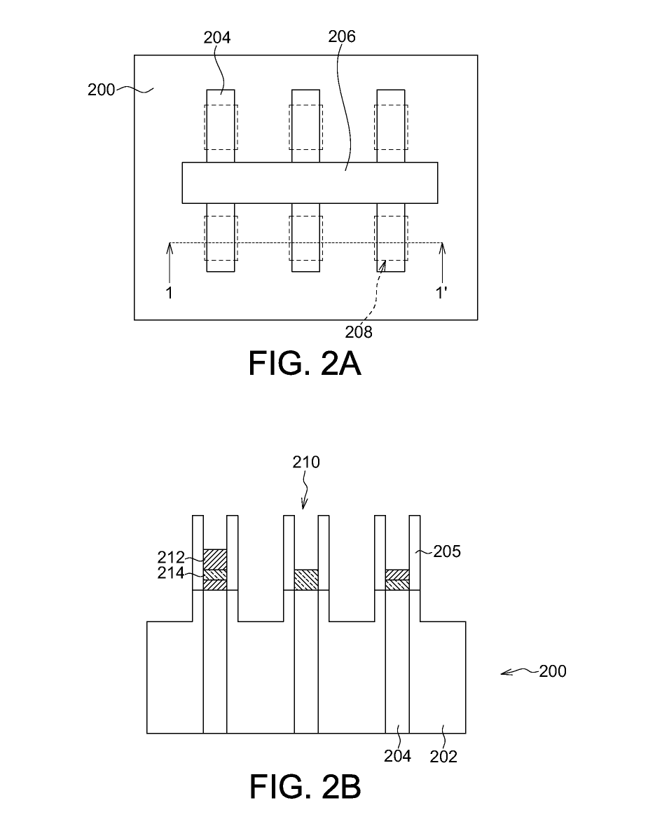

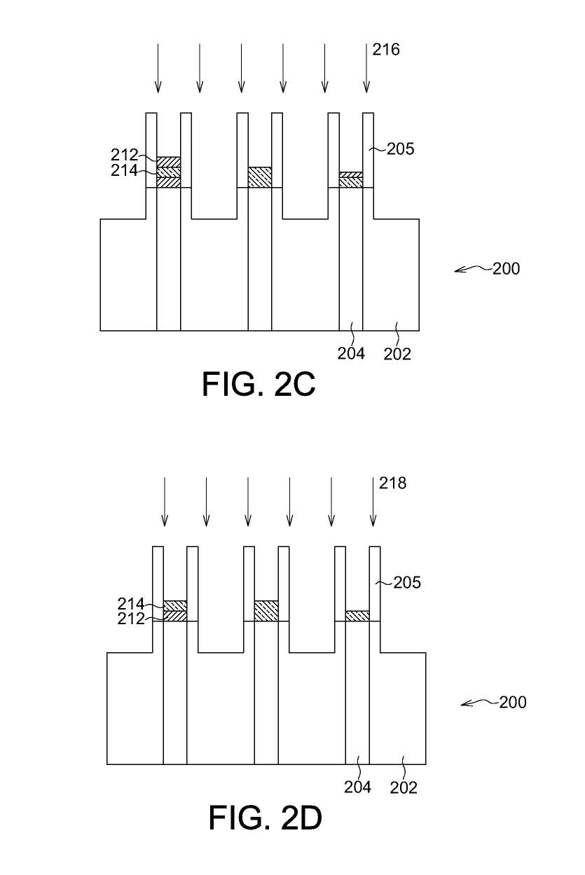

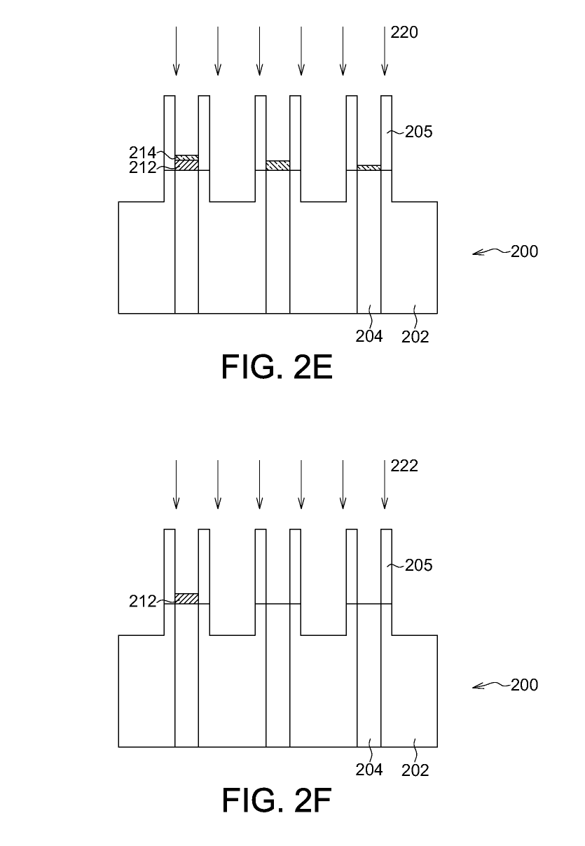

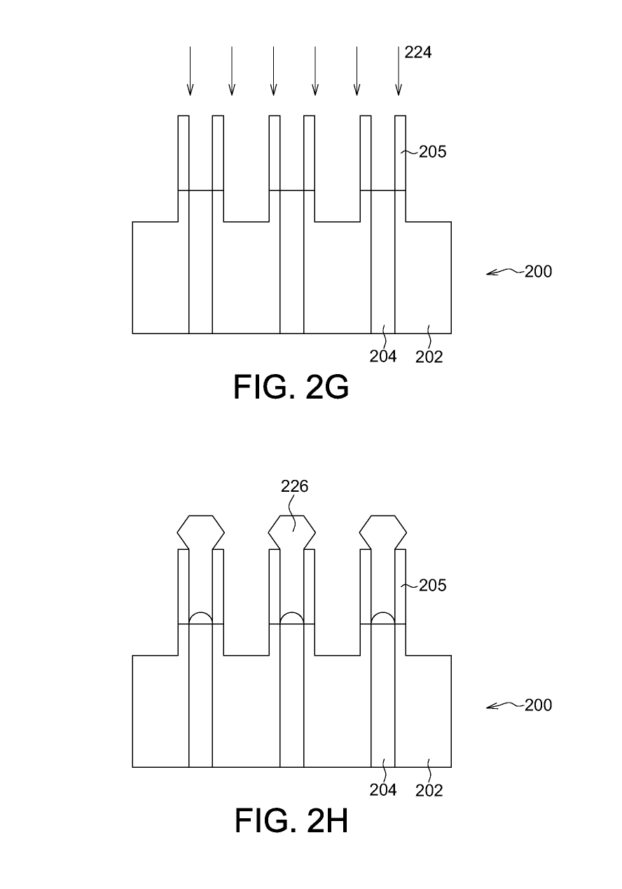

Now the disclosure is directed to details of a method for manufacturing a semiconductor structure according to embodiments. FIG. 1 shows the sequence of the steps of such a method. FIGS. 2A-2H show stages of a semiconductor structure manufactured by the method. It is to be noted that some elements may be omitted from the figures, and the elements in the figures may not reflect their real sizes and configurations.

The method illustrated here can be applied to a bare silicon substrate. Alternatively, the method may be applied to a substrate having a preliminary structure that has been formed by some steps. An exemplary preliminary structure is shown in FIG. 2A. The preliminary structure may comprise a substrate 200 including a plurality of fins 204. The fins 204 may be isolated from one another by shallow trench isolation (STI) structures 202 (shown in FIG. 2B). Further, spacers 205 (shown in FIG. 2B) may be formed on sidewalls of the fins 204. A plurality of gate structures 206 are formed over and across the fins 204. In FIG. 2A, three fins 204 and a gate structure 206 are exemplarily shown.

Then, the method according to an embodiment of the present invention begins. In the step 102, a recess 210 is formed in the substrate 200, as shown in FIG. 2B, which illustrates a cross-sectional view taken along the line 1-1′ in FIG. 2A. It to be noted that, in this disclosure, the singular forms “a,” “an” and “the” are intended to include the plural forms as well, unless the context clearly indicates otherwise. For example, a plurality recesses 210 may be formed. The recess 210 may be provided for the formation of an epitaxial structure (such as the epitaxial structure 226 shown in FIG. 2H). In some embodiments, as shown in FIG. 2B, the recess 210 is formed in a fin 204 of the substrate 200. The recess 210 may be formed in a region 208 indicated in FIG. 2A. Some residuals, such as polymer residuals 212 and oxide residuals 214, may remain in the recess 210 after this step.

In the step 104, at least one wet cleaning process is performed to the recess 210 and the substrate 200. For example, three wet cleaning process can be performed. As shown in FIG. 2C, a first wet cleaning process 216 may be used to remove at least some of the polymer residuals 212, which may be residuals or byproducts of a photo resist layer. As shown in FIG. 2D, a second wet cleaning process 218 may be used to further remove the remaining polymer residuals 212. As shown in FIG. 2E, a third wet cleaning process 220 may be used to remove the oxide residuals 214, which may be native oxides. According to some embodiments, a wet cleaning process can be performed using at least one etchant selected from the group consisting of: SPM (H₂SO₄+H₂O₂), HPM (HCl+H₂O₂+H₂O), and APM (NH₄OH+H₂O₂+H₂O).

In the step 106, a baking process 222 is performed to the recess 210 and the substrate 200 in an atmosphere containing H₂ gas, as shown in FIG. 2F. The baking process 222 can be used to ensure a complete removal of the oxide residuals 214. In some embodiments, the baking process 222 is performed at a temperature between 550° C. and 850° C.

In the step 108, a dry cleaning process 224 is performed to the recess 210 and the substrate 200, as shown in FIG. 2G. Thus, the polymer residuals 212 under the oxide residuals 214 can be removed after the baking process 222. According to some embodiments, the dry cleaning process 224 may comprise applying a plasma, such as a remotely-generated plasma, to the recess 210 and the substrate 200 such that undesired residuals (such as the remaining polymer residuals 212) are reacted with the plasma as well as performing a thermal process to remove the reacted undesired residuals. In particular, the plasma may be formed using NH₃ gas and NF₃ gas. The thermal process can be performed, such as using a hot plate, at a temperature equal to or higher than 100° C.

Optionally, before the step of forming components in the recess 210, an additional clean step 110 may be performed. For example, another baking process can be performed to the recess 210 and the substrate 200 in an atmosphere containing H₂ gas. Similarly, this baking process can be performed at a temperature between 550° C. and 850° C.

After the steps as described above, a starting surface having good surface characteristics can be provided in the recess 210. As such, it is suitable to perform a formation step 112 now. For example, an epitaxial structure 226 may be formed in the recess 210, as shown in FIG. 2H, such as by an epitaxial deposition process. According to some embodiments, the epitaxial structure 226 may comprise at least one material selected from the group consisting of: SiP, SiGe, SiC, and SiGeC. The epitaxial structure 226 may be a source/drain structure.

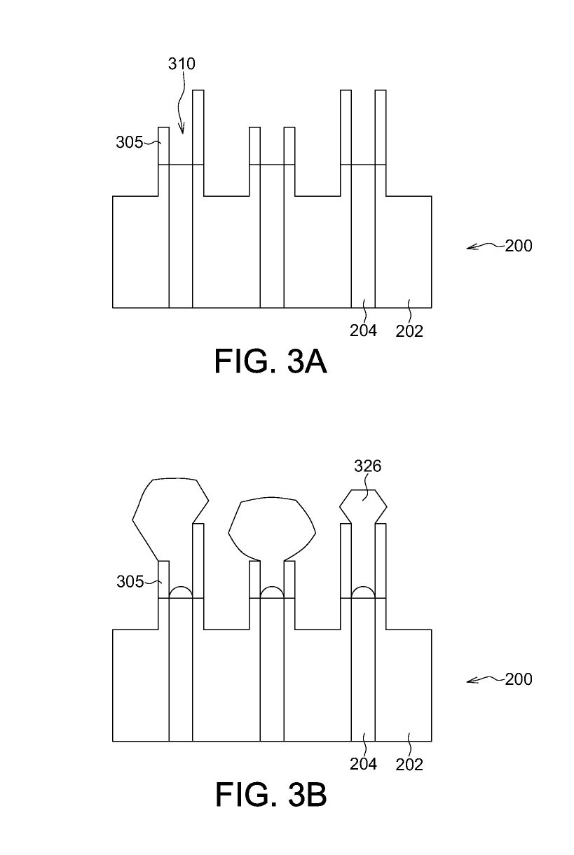

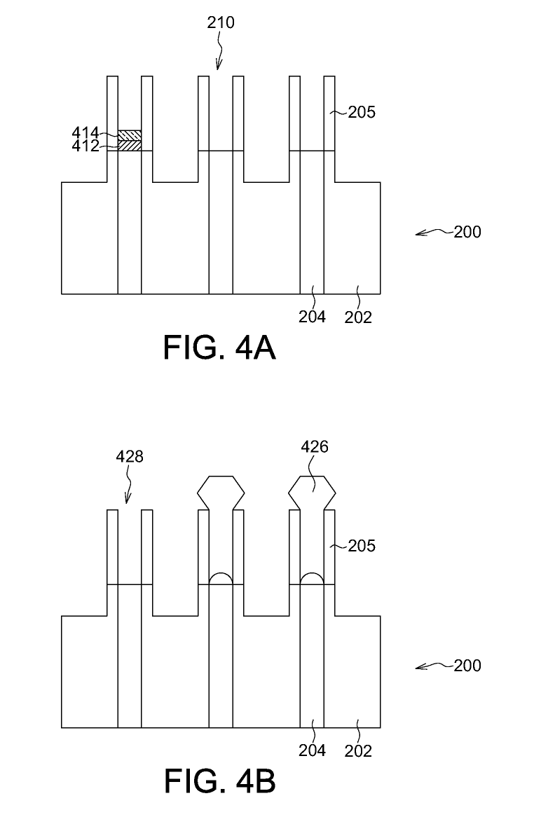

If the cleaning processes before the epitaxial deposition process are too powerful, as shown in FIG. 3A, the spacers 305 and thereby the recess 310 may be damaged. As such, the epitaxial structure 326 may over-grow, as shown in FIG. 3B. It such a condition, undesired contact with other conductive components may be formed, and thus lead to short in the semiconductor structure. An example of such case is using HF in the third wet cleaning process 220. In contrast, if the cleaning process is insufficient, as shown in FIG. 4A, residuals 412 and 414 may remain in the recess 210. As such, as shown in FIG. 4B, the epitaxial structure 426 may not grow to its ideal configuration, even lead to a “miss” 428. An example of such case is directly performing the dry cleaning process 224 after the third wet cleaning process 220 without the baking process 222. In such example, the oxide residuals 214 may not be removed completely, and the polymer residuals 212 under the oxide residuals 214 will remain to the end of the cleaning processes. Both conditions are disadvantageous for the yield of the semiconductor devices.

Compared to typical manufacturing methods, the method according to the embodiments can provide a starting surface with only 10%, or even 1% undesired residuals to the epitaxial deposition process. As such, the yield of the semiconductor devices can be improved. Furthermore, queue time between the recess-forming step and the cleaning processes can be prolonged, and thus a further tolerance is provided in the manufacturing process of the semiconductor devices.

It will be apparent to those skilled in the art that various modifications and variations can be made to the disclosed embodiments. It is intended that the specification and examples be considered as exemplary only, with a true scope of the disclosure being indicated by the following claims and their equivalents.

1. A method for manufacturing a semiconductor structure, comprising:
forming a recess in a substrate;
performing at least one wet cleaning process to the recess and the substrate, wherein the wet cleaning process is performed using at least one etchant selected from the group consisting of: SPM (H₂SO₄+H₂O₂), HPM (HCl+H₂O₂+H₂O), and APM (NH₄OH+H₂O₂+H₂O);
performing a baking process to the recess and the substrate in an atmosphere containing H₂ gas; and
after the baking process, performing a dry cleaning process to the recess and the substrate.

2. The method according to claim 1, wherein the recess is formed in a fin of the substrate.

3. (canceled)

4. The method according to claim 1, wherein the baking process is performed at a temperature between 550° C. and 850° C.

5. The method according to claim 1, wherein the dry cleaning process comprises:
applying a plasma to the recess and the substrate such that undesired residuals are reacted with the plasma; and
performing a thermal process to remove the reacted undesired residuals.

6. The method according to claim 5, wherein the plasma is formed using NH₃ gas and NF₃ gas.

7. The method according to claim 5, wherein the thermal process is performed at a temperature equal to or higher than 100° C.

8. The method according to claim 1, further comprising:
after the dry cleaning process, forming an epitaxial structure in the recess.

9. The method according to claim 8, wherein the epitaxial structure comprises at least one material selected from the group consisting of: SiP, SiGe, SiC, and SiGeC.

10. The method according to claim 8, wherein the epitaxial structure is a source/drain structure.

11. The method according to claim 8, further comprising:
after the dry cleaning process and before forming the epitaxial structure, performing another baking process to the recess and the substrate in an atmosphere containing H₂ gas.

12. The method according to claim 11, wherein the another baking process is performed at a temperature between 550° C. and 850° C.
